(19) United States
(12) Patent Application Publication
(10) Pub. No.: US 2026/0202750 A1
(43) Pub. Date: Jul. 16, 2026

(54) LITHOGRAPHY SYSTEM HAVING MULTILAYER OPTICAL FILTER AND RELATED METHODS

(71) Applicant: Taiwan Semiconductor Manufacturing Company Limited, Hsin-Chu (TW)

(72) Inventors: Hao-Ming CHANG, Pingtung city (TW); Kuan-Hsun WANG, Hsin-Chu (TW); Tzu-Yu LIN, Hsin-Chu (TW); Chun-Lang CHEN, Tainan County (TW); Hsin-Fu TSENG, Hsinchu County (TW)

(21) Appl. No.: 19/015,953

(22) Filed: Jan. 10, 2025

(51) Int. Cl. G03F 7/00

(52) U.S. Cl. CPC G03F 7/70033; G03F 7/70983

(57) ABSTRACT

A method is provided. The method includes: generating first light by a plasma of a light source of a semiconductor processing tool, the first light including in-band light in an extreme ultraviolet (EUV) spectrum and out-of-band (OOB) light outside the EUV spectrum; generating filtered light including the in-band light by removing the OOB light from the first light by a filter assembly positioned in direct contact with a tube, the filter assembly having a filter element that includes a zirconium-based layer and a transition-metal-based layer on the zirconium-based layer; determining whether the filter assembly is degraded; in response to the filter assembly being degraded, performing a maintenance operation on the filter assembly; and in response to the filter assembly not being degraded, performing a semiconductor process on a semiconductor wafer by the semiconductor processing tool.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic view of a system, in accordance with some embodiments.

FIG. 1B illustrates a schematic view of a system, in accordance with some embodiments.

FIG. 1C illustrates a schematic view of a light source of the system of FIG. 1B, in accordance with some embodiments.

FIG. 1D illustrates a diagrammatic view of an optical path of the systems of FIGS. 1A-1C, in accordance with some embodiments.

FIG. 2A illustrates a schematic view of a filter assembly, in accordance with some embodiments.

FIG. 2B illustrates a schematic view of a filter element, in accordance with some embodiments.

FIG. 2C illustrates a schematic view of a filter element, in accordance with some embodiments.

FIG. 2D illustrates a schematic view of a filter element, in accordance with some embodiments.

FIG. 3A illustrates a schematic cross-sectional side view of a filter element, in accordance with some embodiments.

FIG. 3B illustrates a schematic cross-sectional side view of a filter element, in accordance with some embodiments.

FIG. 4A illustrates a schematic view of a filter degradation detection system, in accordance with some embodiments.

FIG. 4B illustrates a schematic view of a filter degradation detection system, in accordance with some embodiments.

FIG. 4C illustrates a schematic view of a filter degradation detection system, in accordance with some embodiments.

FIG. 5 illustrates a schematic view of a filter assembly monitoring system, in accordance with some embodiments.

FIG. 6 is a flow diagram illustrating a method, in accordance with some embodiments.

FIG. 7 is a flow diagram illustrating a method, in accordance with some embodiments.

FIG. 8 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, high volume manufacturing implements actinic inspection. Actinic inspection relies on extreme ultraviolet (EUV) emission and includes post-algorithmic calculations. As a result, lifetime extension of components of an actinic inspection system is beneficial. Actinic inspection systems can include a zirconium filter that is operable to remove light that is outside an EUV spectrum (about 13.5 nanometers or “nm”) to maintain EUV light of high quality. Use of the Zr filter in actinic inspection systems can result in a variety of bottlenecks, one of which is brightness decay, which can result from oxidization of the Zr filter. The Zr filter may also face the risk of tin debris attack, in which tin debris having high momentum can penetrate the Zr filter, resulting in holes in the Zr filter. Once the holes are formed in the Zr filter, undesired heat from out-of-band (OOB) spectrum light, which can primarily be in 100nm-800nm and >1000nm ranges, can degrade following mirror(s) which also results in damage to the mirror.

In embodiments of the disclosure, a filter element of the Zr filter includes a Zr-based layer and a capping layer that protects against degradation of the Zr-based layer. The degradation can a result of oxidization, holes, or both. In some embodiments, the filter element further includes a transition-metal-based layer between the capping layer and the Zr-based layer, which can be beneficial to reflect away OOB spectrum light prior to reaching the Zr-based layer. In some embodiments, one or more of surfaces of the filter element is surface treated to be hydrophobic. In the filter element, substantially only in-band spectrum EUV light is transmitted, while the OOB spectrum light is reflected, absorbed or both. The filter element is beneficial to prevent oxidization, enhance strength thereof, and prolong tool operation time.

Embodiments of the disclosure further provide detection of degradation of the filter element. In some embodiments, EUV brightness entering and leaving the filter element is detected to determine whether the filter element is degraded. In some embodiments, a pressure differential measured on either side of the filter element is measured to determine whether the filter element is degraded. For example, pores that extend through the filter element may result in a very low pressure differential, which can indicated degradation of the filter element. In some embodiments, focal distance of one or more mirrors of the system is measured over time, and a shift in the focal distance is used to determine whether the filter element is degraded. As a result, timely determination of filter element degradation is performed, resulting in a reliable process flow for the system that includes the filter element.

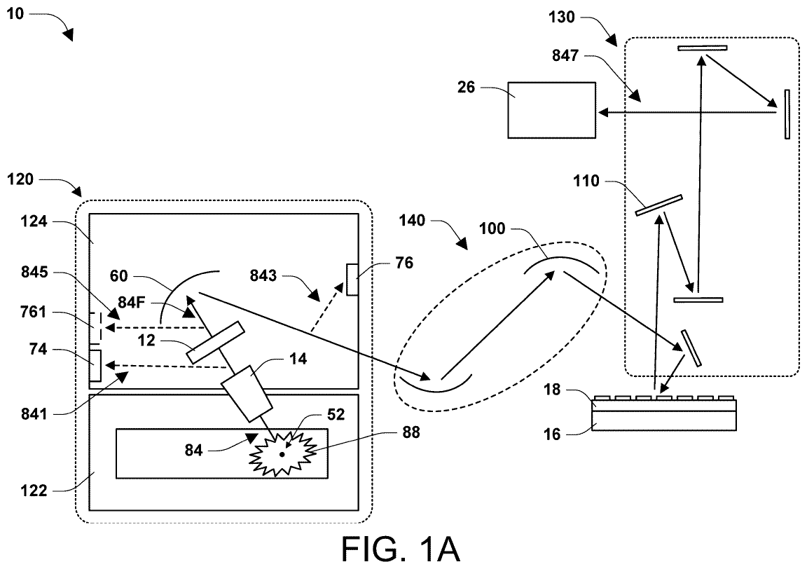

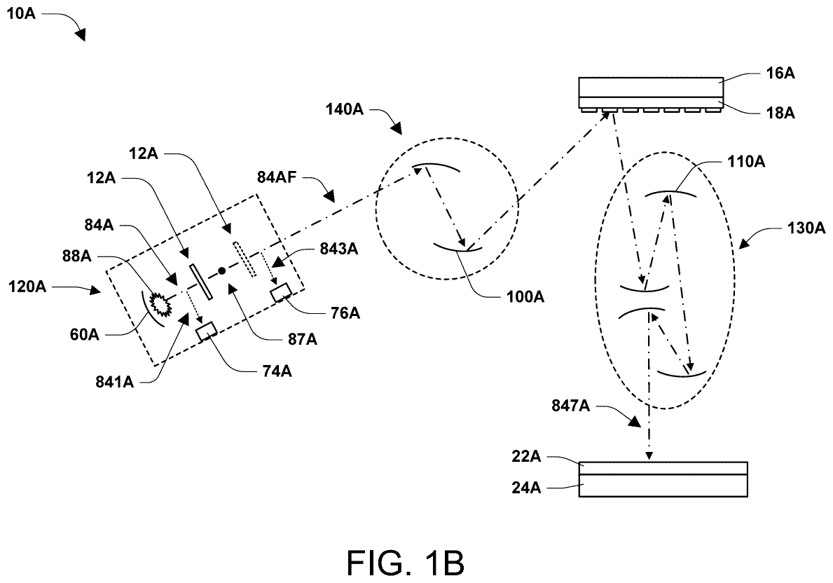

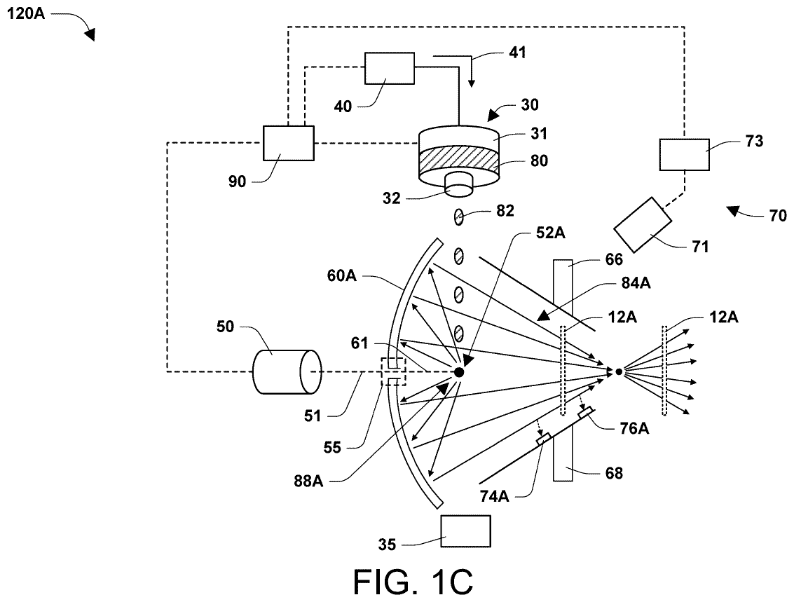

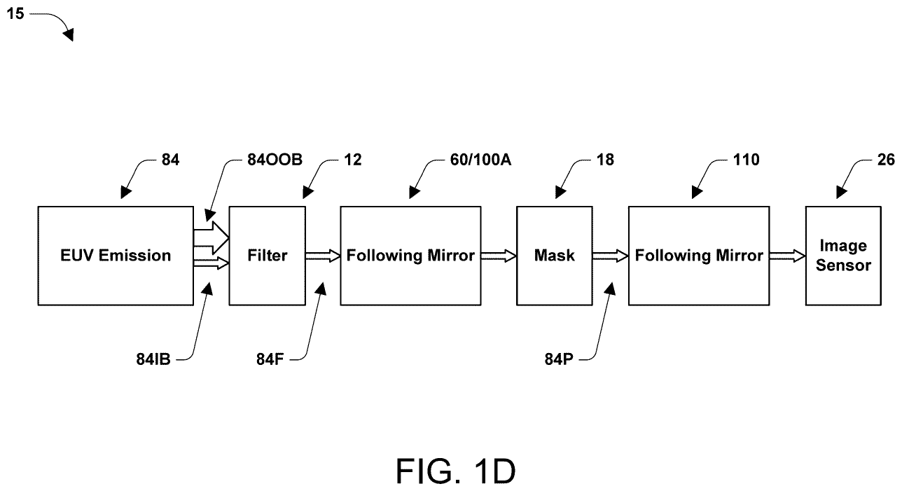

FIG. 1A illustrates a schematic view of a system 10, in accordance with some embodiments. In some embodiments, the system 10 is a lithography system, such as a lithography exposure system, and can be referred to as the lithography system 10 or the lithography exposure system 10. In some embodiments, the system 10 is a semiconductor processing tool, and can be referred to as the semiconductor processing tool 10.

In some embodiments, the system 10 is an extreme ultraviolet (EUV) lithography system designed to expose a resist layer by EUV radiation. The system 10 includes a light source 120, an illuminator 140, a mask stage 16, a projection optics module (or projection optics box (POB)) 130 and a substrate stage, in accordance with some embodiments. In some embodiments, the system 10 includes an image sensor 26 that can be positioned where the substrate stage would normally be positioned. Namely, the system 10 may include the image sensor 26 in a first operation (e.g., a measurement operation) and may include the substrate stage in a second operation (e.g., a lithography exposure operation). The elements of the system 10 can be added to or omitted, and the disclosure should not be limited by the embodiment. Some elements of the system 10 may be rearranged in other embodiments. For example, position of a collector mirror 60 relative to a lighting point 52 and the illuminator 140 may be different than that depicted in FIG. 1A. An embodiment including a collector mirror 60A arranged differently than the collector mirror 60 is depicted in, and described with reference to, FIGS. 1B and 1C. The collector mirrors 60, 60A may each be referred to as a collector.

The light source 120 is configured to generate light radiation 84 (or “first light 84”) having a wavelength ranging between about 1 nm and about 100 nm in certain embodiments. In one particular example, the light source 120 generates an EUV radiation 84 with a wavelength centered at about or substantially at 13.5 nm. Accordingly, the light source 120 is also referred to as an EUV radiation source. However, it should be appreciated that the light source 120 should not be limited to emitting EUV radiation 84. The light source 120 can be utilized to perform any high-intensity photon emission from excited target fuel.

The light source 120 includes a first chamber 122 and a second chamber 124 that are in optical communication with each other via a transport tube 14. The first chamber 122 may be operated at a first pressure, and the second chamber 124 may be operated at a second pressure that is different than the first pressure.

In some embodiments, the light source 120 includes a droplet generator that delivers a target fuel to a zone of excitation at which at least one laser pulse from a laser generator hits the droplets. In an embodiment, the target fuel includes tin (Sn). The laser generator is configured to generate at least one laser pulse to allow the conversion of the droplets into plasma 88. In some embodiments, the laser generator is configured to produce a laser pulse to the lighting point 52 to convert the droplets to plasma 88 which generates EUV radiation 84. The laser pulse can be directed through a window (or lens), and irradiate droplets at the lighting point 52. In some embodiments, the lighting point 52 is in the first chamber 122.

The plasma 88 emits EUV radiation 84, which is collected by the collector 60 and directed toward the illuminator 140. The collector 60 reflects and focuses the EUV radiation 84 for the lithography processes performed through an exposure tool, such as the system 10. In some embodiments, the collector 60 is in the second chamber 124.

In some embodiments, the laser generator is a carbon dioxide (CO2) laser source. In some embodiments, the laser generator is used to generate the laser pulse with single wavelength. The laser pulse can be transmitted through an optic assembly for focusing and determining incident angle of the laser pulse. In some embodiments, the laser pulse has a spot size of about 200-300 μm, such as 225 μm. The laser pulse is generated to have certain driving power to meet wafer production targets, such as a throughput of 125 wafers per hour (WPH), though greater WPH may be achieved. In some embodiments, the laser pulse is equipped with about 23 kW driving power. In various embodiments, the driving power of the laser pulse is at least 20 kW, such as 27 kW.

In various embodiments, the illuminator 140 includes various refractive optic components, such as a single lens or a lens system having multiple reflectors 100, for example lenses (zone plates) or alternatively reflective optics (for EUV lithography exposure system), such as a single mirror or a mirror system having multiple mirrors in order to direct light from the light source 120 onto the mask stage 16, particularly to a mask 18 secured on the mask stage 16. In the present embodiment where the light source 120 generates light in the EUV wavelength range, reflective optics are employed. In some embodiments, the illuminator 140 includes at least three lenses.

The mask stage 16 is configured to secure the mask 18. In some embodiments, the mask stage 16 includes an electrostatic chuck (e-chuck) to secure the mask 18. This is because gas molecules absorb EUV radiation and the lithography exposure system for the EUV lithography patterning is maintained in a vacuum environment to avoid EUV intensity loss. In the present disclosure, the terms mask, photomask, and reticle are used interchangeably. In the present embodiment, the mask 18 is a reflective mask. One exemplary structure of the mask 18 includes a substrate with a suitable material, such as a low thermal expansion material (LTEM) or fused quartz. In various examples, the LTEM includes TiO₂ doped SiO₂, or other suitable materials with low thermal expansion. The mask 18 includes a reflective multilayer deposited on the substrate.

The projection optics module (or projection optics box (POB)) 130 is configured for imaging the pattern of the mask 18 on to a semiconductor wafer secured on a substrate stage of the system 10. In some embodiments, the POB 130 has refractive optics (such as for a UV lithography exposure system) or alternatively reflective optics (such as for an EUV lithography exposure system) in various embodiments, e.g., optics 110. The light directed from the mask 18, carrying the image of the pattern defined on the mask, is collected by the POB 130. The illuminator 140 and the POB 130 are collectively referred to as an optical module of the system 10. In some embodiments, the POB 130 includes at least five reflective optics.

In some embodiments, the semiconductor wafer is made of silicon or other semiconductor materials. Alternatively, or additionally, the semiconductor wafer may include other elementary semiconductor materials such as germanium (Ge). In some embodiments, the semiconductor wafer is made of a compound semiconductor such as silicon carbide (SiC), gallium arsenic (GaAs), indium arsenide (InAs), or indium phosphide (InP). In some embodiments, the semiconductor wafer is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer may be a silicon-on-insulator (SOI) or a germanium-on-insulator (GOI) substrate.

In some embodiments, the system 10 is operable to perform one or more semiconductor manufacturing process operations on the semiconductor wafer. The semiconductor wafer (or simply “the wafer”) comprises at least one of a substrate, a photomask, a semiconductor device, a dielectric layer, an epitaxial layer, a silicon-on-insulator (SOI) structure, a semiconductor layer, a conductive material layer, a die, etc. The semiconductor wafer comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor wafer comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor wafer are within the scope of the present disclosure.

The semiconductor wafer may have various device elements. Examples of device elements that are formed in the semiconductor wafer include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the semiconductor wafer is coated with a resist layer sensitive to the EUV radiation. Various components including those described above are integrated together and are operable to perform lithography processes.

The system 10 may include other modules or be integrated with (or be coupled with) other modules, such as a cleaning module designed to provide hydrogen gas to the light source 120. The hydrogen gas helps reduce contamination in the light source 120.

The system 10 includes a filter assembly 12. The filter assembly 12 is positioned in the second chamber 124. In operation, when light radiation 84 that includes in-band light (e.g., EUV light) and OOB light is incident on the filter assembly 12, the filter assembly 12 can remove the OOB light while allowing the in-band light (e.g., EUV light) to pass through. Removing the OOB light is beneficial because heat from the OOB light, which can reside in the 100 nm-800 nm and >1000nm ranges, can degrade following mirrors, such as the collector mirror 60. Over time, a filter element of the filter assembly 12 can degrade, for example, due to oxidization or holes being formed therethrough. The oxidization can result in reduction in brightness of the in-band light. The holes in the filter element can result in passage of the OOB light to the following mirror(s), which can result in heating of the mirror(s) that can damage the mirror(s). For example, the heating can increase formation of oxides, hydrocarbons or both on the surface of the affected mirror(s), such as the collector mirror 60. The oxidization or increase of hydrocarbon film on the collector mirror 60 or the mirrors 100, 110 of the illuminator 140 or the POB 130, can reduce brightness of the in-band light, which reduces throughput of the system 10.

In some embodiments, a filter monitoring system or a portion thereof is positioned in the second chamber 124. The filter monitoring system can include a first sensor 74 and a second sensor 76. The filter monitoring system is operable to determine whether the filter element of the filter assembly 12 is degraded.

In operation, filtered light 84F including the in-band light is generated by removing the OOB light from the first light 84 by the filter assembly 12 that is positioned between the plasma 88 and the collector mirror 60. Prior to generating the filtered light 84F, a first portion 841 of the first light 84 is received by a first sensor 74. Following generating the filtered light 84F, a second portion 843 of the filtered light 84F is received by a second sensor 76. As depicted in FIG. 1A, the first sensor 74 can be positioned to receive the first portion 841 that is part of the first light 84 that is incident on the filter assembly 12, and the second sensor 76 can be positioned to receive the second portion 843 that is reflected from the collector mirror 60. In some embodiments, a second sensor 761 is positioned to receive a second portion 845 that is a part of the filtered light 84F that is incident on the collector mirror 60 instead of reflected by the collector mirror 60. The second sensor 761 is depicted in phantom in FIG. 1A. In some embodiments, the first and second sensors 74, 76 are positioned on different (e.g., opposing) walls of the second chamber 124. In some embodiments, the first and second sensors 74, 761 are positioned on the same wall of the second chamber 124.

In some embodiments, instead of, or in addition to, obtaining the second portion 843 or the second portion 845, output light 847 is received by the image sensor 26 from the POB 130. The output light 847 can also be referred to as a “second portion.”

In operation, the first sensor 74 can be operated to generate a first brightness value associated with the first portion 841, and the second sensor 76, the second sensor 761 or the image sensor 26 can be operated to generate a second brightness value associated with the second portion 843, the second portion 845, or the output light 847, respectively. Then, a brightness difference value can be determined based on the first brightness value and the second brightness value. For example, the second brightness value may be subtracted from the first brightness value to determine the brightness difference value. The filtered light 84F does not substantially include the OOB light. When the first sensor 74, for example, is sensitive to the OOB light in addition to the in-band light, the first brightness measured by the first sensor 74 can have a portion that is associated with the OOB light. In calculating the brightness difference value, the portion associated with the OOB light may be removed, for example, by software. In some embodiments, the first sensor 74 is sensitive to the in-band light but attenuates or is entirely insensitive to the OOB light. In such embodiments, the portion associated with the OOB light may be removed by the first sensor 74 instead of by software.

Based on the brightness difference value, determination can be made whether the filter element of the filter assembly 12 is degraded. For example, a determination can be made whether the brightness difference value exceeds a threshold value. In response to the brightness difference value not exceeding the threshold value, it can be determined that the filter element is not degraded, and a semiconductor process (e.g., lithography) can be performed on the semiconductor wafer by the system 10. In response to the brightness difference value exceeding the threshold value, it can be determined that the filter element is degraded, and a maintenance operation can be performed on the filter assembly, such as removing, replacing, or repairing the filter element.

FIG. 1B illustrates a schematic view of a system 10A, in accordance with some embodiments. FIG. 1C illustrates a schematic view of a light source 120A of the system 10A of FIG. 1B, in accordance with some embodiments. In some embodiments, the system 10A is a lithography system, such as a lithography exposure system, and can be referred to as the lithography system 10A or the lithography exposure system 10A. In some embodiments, the system 10A is a semiconductor processing tool, and can be referred to as the semiconductor processing tool 10A.

FIG. 1B illustrates a schematic and diagrammatic view of the lithography exposure system 10A, in accordance with some embodiments. In some embodiments, the lithography exposure system 10A is an extreme ultraviolet (EUV) lithography system designed to expose a resist layer by EUV radiation, and may also be referred to as the EUV system 10A. The lithography exposure system 10A includes a light source 120A, an illuminator 140A, a mask stage 16A, a projection optics module (or projection optics box (POB)) 130A and a wafer stage 24A, in accordance with some embodiments. The elements of the lithography exposure system 10A can be added to or omitted, and the disclosure should not be limited by the embodiment.

The light source 120A is configured to generate light radiation 84A having a wavelength ranging between about 1 nm and about 100 nm in certain embodiments. In one particular example, the light source 120A generates an EUV radiation 84A with a wavelength centered at about 13.5 nm. Accordingly, the light source 120A is also referred to as an EUV radiation source. However, it should be appreciated that the light source 120A should not be limited to emitting EUV radiation 84. The light source 120A can be utilized to perform any high-intensity photon emission from excited target fuel.

In various embodiments, the illuminator 140A includes various refractive optic components, such as a single lens or a lens system having multiple reflectors 100A, for example lenses (zone plates) or alternatively reflective optics (for EUV lithography exposure system), such as a single mirror or a mirror system having multiple mirrors in order to direct light from the light source 120A onto the mask stage 16A, particularly to a mask 18A secured on the mask stage 16A. In the present embodiment where the light source 120A generates light in the EUV wavelength range, reflective optics are employed. In some embodiments, the illuminator 140 includes at least two lenses.

The mask stage 16A is configured to secure the mask 18A. In some embodiments, the mask stage 16A includes an electrostatic chuck (e-chuck) to secure the mask 18A. This is because gas molecules absorb EUV radiation and the lithography exposure system for the EUV lithography patterning is maintained in a vacuum environment to avoid EUV intensity loss. In the present disclosure, the terms mask, photomask, and reticle are used interchangeably. In the present embodiment, the mask 18A is a reflective mask. One exemplary structure of the mask 18A includes a substrate with a suitable material, such as a low thermal expansion material (LTEM) or fused quartz. In various examples, the LTEM includes TiO₂ doped SiO₂, or other suitable materials with low thermal expansion. The mask 18A includes a reflective multilayer deposited on the substrate.

The projection optics module (or projection optics box (POB)) 130A is configured for imaging the pattern of the mask 18A on to a semiconductor wafer 22A secured on the wafer stage 24A of the lithography exposure system 10A. In some embodiments, the POB 130A has refractive optics (such as for a UV lithography exposure system) or alternatively reflective optics (such as for an EUV lithography exposure system) in various embodiments, e.g., optics 110A. The light directed from the mask 18A, carrying the image of the pattern defined on the mask, is collected by the POB 130A. The illuminator 140A and the POB 130A are collectively referred to as an optical module of the lithography exposure system 10A. In some embodiments, the POB 130A includes at least five reflective optics.

In some embodiments, the semiconductor wafer 22A is made of silicon or other semiconductor materials. Alternatively or additionally, the semiconductor wafer 22A may include other elementary semiconductor materials such as germanium (Ge). In some embodiments, the semiconductor wafer 22A is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22A may be a silicon-on-insulator (SOI) or a germanium-on-insulator (GOI) substrate.

In some embodiments, the system 10A is operable to perform one or more semiconductor manufacturing process operations on the semiconductor wafer 22A. The semiconductor wafer 22A (or simply “the wafer 22A”) comprises at least one of a substrate, a photomask, a semiconductor device, a dielectric layer, an epitaxial layer, a silicon-on-insulator (SOI) structure, a semiconductor layer, a conductive material layer, a die, etc. The semiconductor wafer 22A comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor wafer 22A comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor wafer are within the scope of the present disclosure.

The semiconductor wafer 22A may have various device elements. Examples of device elements that are formed in the semiconductor wafer 22A include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the semiconductor wafer 22A is coated with a resist layer sensitive to the EUV radiation. Various components including those described above are integrated together and are operable to perform lithography processes.

The system 10A includes a filter assembly 12A. The filter assembly 12A is positioned in between plasma 88A and a focal point 87A. In some embodiments, the focal point 87A is positioned between the plasma 88A and the filter assembly 12A, as depicted in phantom in FIG. 1B.

In operation, when light radiation 84A emitted by the plasma 88A that includes in-band light (e.g., EUV light) and OOB light is incident on the filter assembly 12A, the filter assembly 12A can remove the OOB light while allowing the in-band light (e.g., EUV light) to pass through. Removing the OOB light is beneficial because heat from the OOB light, which can reside in the 100 nm-800nm and >1000nm ranges, can degrade following mirrors, such as the mirror(s) 100A. Over time, a filter element of the filter assembly 12A can degrade, for example, due to oxidization or holes being formed therethrough. The oxidization can result in reduction in brightness of the in-band light. The holes in the filter element can result in passage of the OOB light to the following mirror(s), which can result in heating of the mirror(s) that can damage the mirror(s). For example, the heating can increase formation of oxides, hydrocarbons or both on the surface of the affected mirror(s), such as the mirror(s) 100A. The oxidization or increase of hydrocarbon film on the mirrors 100A, 110A of the illuminator 140A or the POB 130A, can reduce brightness of the in-band light, which reduces throughput of the system 10A.

In some embodiments, a filter monitoring system or a portion thereof is positioned in the light source 120A. The filter monitoring system can include a first sensor 74A and a second sensor 76A. The filter monitoring system is operable to determine whether the filter element of the filter assembly 12A is degraded.

In operation, filtered light 84AF including the in-band light is generated by removing the OOB light from the first light 84A by the filter assembly 12A that is positioned between the plasma 88A and focal point 87A or after the focal point 87A. Prior to generating the filtered light 84AF, a first portion 841A of the first light 84A is received by the first sensor 74A. Following generating the filtered light 84AF, a second portion 843A of the filtered light 84AF is received by a second sensor 76A. As depicted in FIG. 1B, the first sensor 74A can be positioned to receive the first portion 841A that is part of the first light 84A that is incident on the filter assembly 12A, and the second sensor 76A can be positioned to receive the second portion 843A that exits the filter assembly 12A. In some embodiments, the first and second sensors 74A, 76A are positioned on different (e.g., opposing) walls of the light source 120A. In some embodiments, the first and second sensors 74A, 76A are positioned on the same wall of the light source 120A.

In some embodiments, instead of, or in addition to, obtaining the second portion 843A, output light 847A is received by an image sensor from the POB 130A. The output light 847A can also be referred to as a “second portion.” The image sensor may be positioned on the wafer stage 24A or in place of the wafer stage 24A. For example, the wafer stage 24A may be moved away from a processing position at which semiconductor processing (e.g., lithographic exposure) is performed to another position, and the image sensor is moved into the processing position or near the processing position previously occupied by the wafer stage 24A to perform detection of the output light 847A.

In operation, the first sensor 74A can be operated to generate a first brightness value associated with the first portion 841A, and the second sensor 76A, or the image sensor can be operated to generate a second brightness value associated with the second portion 843A or the output light 847A, respectively. Then, a brightness difference value can be determined based on the first brightness value and the second brightness value. For example, the second brightness value may be subtracted from the first brightness value to determine the brightness difference value. The filtered light 84AF does not substantially include the OOB light. When the first sensor 74A, for example, is sensitive to the OOB light in addition to the in-band light, the first brightness measured by the first sensor 74A can have a portion that is associated with the OOB light. In calculating the brightness difference value, the portion associated with the OOB light may be removed, for example, by software. In some embodiments, the first sensor 74A is sensitive to the in-band light but attenuates or is entirely insensitive to the OOB light. In such embodiments, the portion associated with the OOB light may be removed by the first sensor 74A instead of by software.

Based on the brightness difference value, determination can be made whether the filter element of the filter assembly 12A is degraded. For example, a determination can be made whether the brightness difference value exceeds a threshold value. In response to the brightness difference value not exceeding the threshold value, it can be determined that the filter element is not degraded, and a semiconductor process (e.g., lithography) can be performed on the semiconductor wafer by the system 10A. In response to the brightness difference value exceeding the threshold value, it can be determined that the filter element is degraded, and a maintenance operation can be performed on the filter assembly, such as removing, replacing, or repairing the filter element.

The lithography exposure system 10A may include other modules or be integrated with (or be coupled with) other modules, such as a cleaning module designed to provide hydrogen gas to the light source 120A. The hydrogen gas helps reduce contamination in the light source 120A. Further description of the light source 120A is provided with reference to FIG. 1C.

In FIG. 1C, the light source 120A is shown in a diagrammatical view, in accordance with various embodiments. In some embodiments, the light source 120A employs a dual-pulse laser produced plasma (LPP) mechanism to generate the plasma 88A and further generate EUV light radiation 84A from the plasma 88A. The light source 120A includes a droplet generator 30, a droplet receptacle 35, a laser generator 50, a laser produced plasma (LPP) collector 60A (also referred to as “the collector 60A”), a monitoring device 70 and a controller 90. Some or all of the above-mentioned elements of the light source 120A may be held under vacuum. It should be appreciated that the elements of the light source 120A can be added to or omitted, and should not be limited by the embodiment.

The droplet generator 30 is configured to generate a plurality of droplets 82, which may be elongated, of a target fuel 80 to a zone of excitation at which at least one laser pulse 51 from the laser generator 50 hits the droplets 82. In an embodiment, the target fuel 80 includes tin (Sn). In an embodiment, the droplets 82 may be formed with an elliptical shape. In an embodiment, the droplets 82 are generated at a rate of about 50 kilohertz (kHz) and are introduced into the zone of excitation in the light source 120A at a speed of about 70 meters per second (m/s). Other material can also be used for the target fuel 80, for example, a tin containing liquid material such as eutectic alloy containing tin, lithium (Li), and xenon (Xe). The target fuel 80 in the droplet generator 30 may be in a liquid phase.

The laser generator 50 is configured to generate at least one laser pulse to allow the conversion of the droplets 82 into the plasma 88A. In some embodiments, the laser generator 50 is configured to produce a laser pulse 51 to the lighting point 52 to convert the droplets 82 to the plasma 88A which generates the light radiation 84A. The laser pulse 51 is directed through window (or lens) 55, and irradiates droplets 82 at the lighting point 52. The window 55 is formed in the collector 60A and adopts a suitable material substantially transparent to the laser pulse 51. The droplet receptacle 35 catches and collects unused droplets 82 and/or scattered material of the droplets 82 resulting from the laser pulse 51 striking the droplets 82.

The plasma emits light radiation 84A, which is collected by the collector 60A and directed toward the focal point 87A. The collector 60A further reflects and focuses the light radiation 84A for the lithography processes performed through an exposure tool. In some embodiments, the collector 60A has an optical axis 61 which is parallel to the direction of the laser pulse 51. In some embodiments, the collector 60A includes at least two collector sections that are arranged concentrically and physically separated from each other. The collector 60A may include a vessel wall 65 having first and second pumps 66, 68 attached thereto. In some embodiments, the first and second pumps 66, 68 include scrubbers configured to remove particulates and/or gases from the collector 60A. The first and second pumps 66, 68 may be collectively referred to as “the pumps 66, 68” herein.

In some embodiments, the laser generator 50 is a carbon dioxide (CO2) laser source. In some embodiments, the laser generator 50 is used to generate the laser pulse 51 with single wavelength. The laser pulse 51 is transmitted through an optic assembly for focusing and determining incident angle of the laser pulse 51. In some embodiments, the laser pulse 51 has a spot size of about 200-300 μm, such as 225 μm. The laser pulse 51 is generated to have certain driving power to meet wafer production targets, such as a throughput of 125 wafers per hour (WPH), though greater WPH may be achieved, for example, by use of the collector 60A which increases throughput by its larger surface area. In some embodiments, the laser pulse 51 is equipped with about 23 kW driving power. In various embodiments, the driving power of the laser pulse 51 is at least 20 kW, such as 27 kW.

The monitoring device 70 is configured to monitor one or more conditions in the light source 120A so as to produce data for controlling configurable parameters of the light source 120A. In some embodiments, the monitoring device 70 includes a metrology tool 71 and an analyzer 73. In cases where the metrology tool 71 is configured to monitor condition of the droplets 82 supplied by the droplet generator 30, the metrology tool may include an image sensor, such as a charge coupled device (CCD), complementary metal oxide semiconductor (CMOS) sensor, or the like. The metrology tool 71 produces a monitoring image including image or video of the droplets 82 and transmits the monitoring image to the analyzer 73. In cases where the metrology tool 71 is configured to detect energy or intensity of the light radiation 84A produced by the droplet 82 in the light source 120A, the metrology tool 71 may include a number of energy sensors. The energy sensors may be any suitable sensors that are able to observe and measure energy of electromagnetic radiation in the ultraviolet region. In some embodiments, the metrology tool 71 can include, supplement or replace the first sensor 74A.

The analyzer 73 is configured to analyze signals produced by the metrology tool 71 and outputs a detection signal to the controller 90 according to an analyzing result. For example, the analyzer 73 includes an image analyzer. The analyzer 73 receives the data associated with the images transmitted from the metrology tool 71 and performs an image analysis process on the images of the droplets 82 in the excitation zone. Afterwards, the analyzer 73 sends data related to the analysis to the controller 90. The analysis may include a flow path error or a position error.

In some embodiments, two or more metrology tools 71 are used to monitor different conditions of the light source 120. One is configured to monitor condition of the droplets 82 supplied by the droplet generator 30, and the other is configured to detect energy or intensity of the EUV light 84 produced by the droplet 82 in the light source 120. In some embodiments, the metrology tool 71 is a final focus module (FFM) and positioned in the laser generator 50 to detect light reflected from the droplet 82.

The controller 90 is configured to control one or more elements of the light source 120A. In some embodiments, the controller 90 is configured to drive the droplet generator 30 to generate the droplets 82. In addition, the controller 90 is configured to drive the laser generator 50 to fire the laser pulse 51. The generation of the laser pulse 51 may be controlled to be associated with the generation of droplets 82 by the controller 90 so as to make the laser pulse 51 hit each droplet 82 in sequence.

In some embodiments, the droplet generator 30 includes a reservoir 31 and a nozzle assembly 32. The reservoir 31 is configured for holding the target fuel 80. In some embodiments, one gas line 41 is connected to the reservoir 31 for introducing pumping gas, such as argon, from a gas source 40 into the reservoir 31. By controlling the gas flow in the gas line 41, the pressure in the reservoir 31 can be manipulated. For example, when gas is continuously supplied into the reservoir 31 via the gas line 41, the pressure in the reservoir 31 increases. As a result, the target fuel 80 in the reservoir 31 can be forced out of the reservoir 31 in the form of droplets 82.

FIG. 1D illustrates a diagrammatic view of an optical path 15 of the systems 10, 10A, in accordance with some embodiments. The optical path 15 is described mainly with reference to the system 10 depicted in FIG. 1A, with some reference to FIG. 1B and FIG. 1C as beneficial to understand the optical path 15 of the system 10A. The optical path 15 of the system 10A is similar in many respects to that of the system 10.

In FIG. 1D, the optical path 15 starts with emission of the light radiation 84 (or the light radiation 84A) that is generated by the plasma 88 (or the plasma 88A). The light radiation 84 includes in-band light 84IB, which can be EUV light, and out-of-band (OOB) light 84OOB, which can be or include infrared light, such as far infrared light.

The filter assembly 12 removes (e.g., partially or fully) the OOB light 84OOB and allows transmission of the in-band light 84IB. The in-band light 84IB that exits the filter assembly 12 is included in or is the filtered light 84F. In some embodiments, the filtered light 84F (or the filtered light 84AF) can include a portion of the OOB light 84OOB. In some embodiments, a ratio of the OOB light 84OOB that exits the filter assembly 12 over the OOB light 84OOB that is incident on the filter assembly 12 does not exceed about 10%, about 5% or about 1%.

In the system 10, the filtered light 84F is incident on and reflected by the collector 60. In the system 10A, the filtered light 84AF is incident on and reflected by the mirror 100A of the illuminator 140A.

The filtered light 84F that exits the illuminator 140 is incident on and reflected by the mask 18. Patterned light 84P carrying the pattern of the mask 18 is then incident on and reflected by the mirrors 110 of the POB 130.

The patterned light 84P exiting the POB 130 is incident on the image sensor 26. In some embodiments, the patterned light 84P is incident on the wafer 22A that is positioned on the wafer stage 24A.

Generally, the filter assembly 12 or the filter assembly 12A is positioned along the optical path 15 between the source of the EUV emission and a mirror that follows the source along the optical path 15. For example, in the system 10 described with reference to FIG. 1A, the filter assembly 12 is positioned between the plasma 88 and the collector 60. In another example, in the system 10A described with reference to FIGS. 1B and 1C, the filter assembly 12A is positioned between the plasma 88A and the first mirror 100A of the illuminator 140A, which follows the collector 60A along the optical path 15.

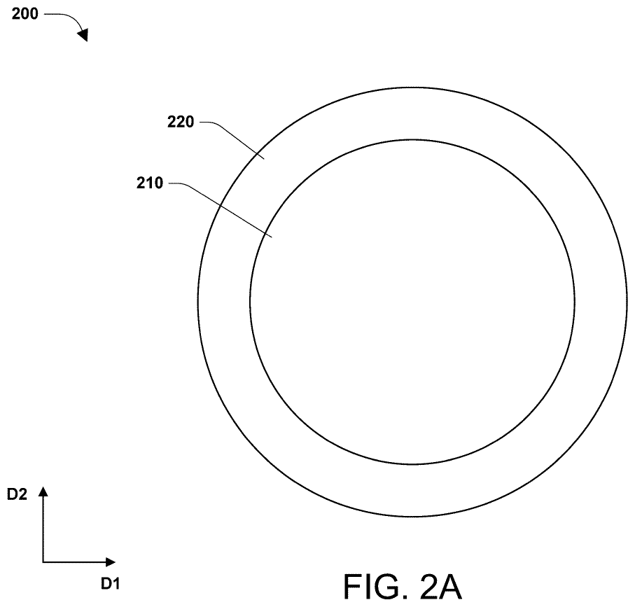

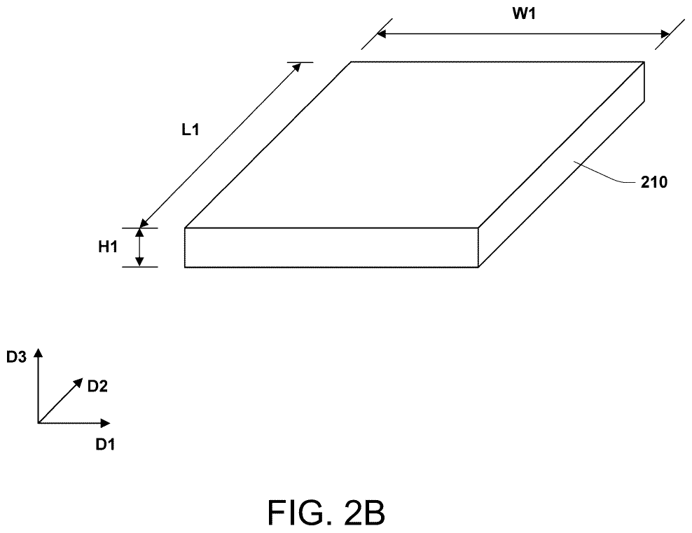

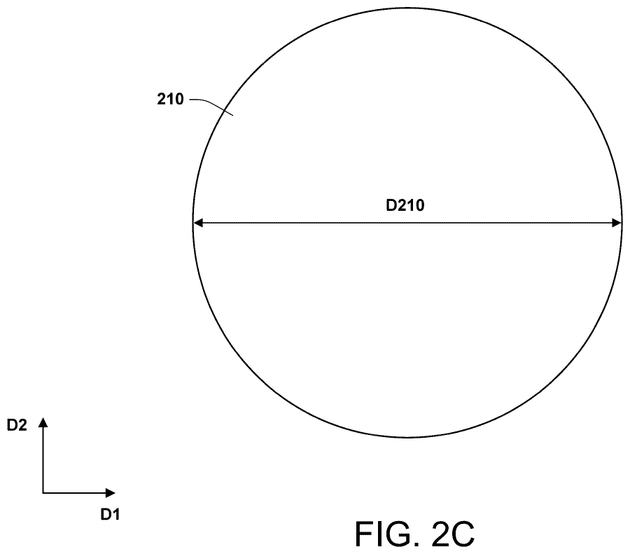

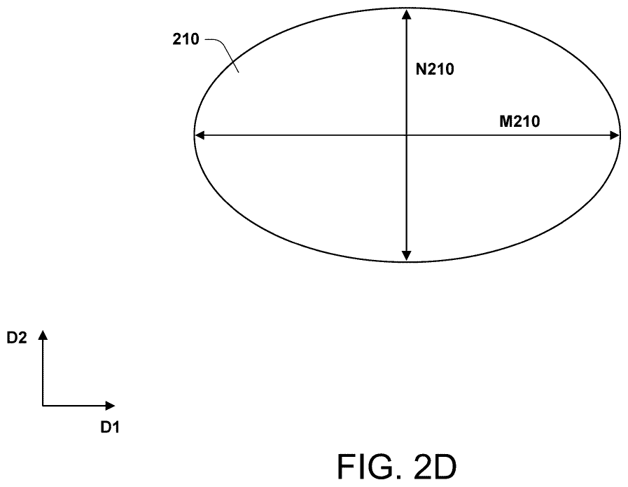

FIG. 2A illustrates a schematic view of a filter assembly 200, in accordance with some embodiments. The filter assembly 200 is an embodiment of the filter assembly 12, the filter assembly 12A, or both.

The filter assembly 200 includes a frame 220 and a filter element 210 positioned on or in the frame 220. The frame 220 can be or include a rigid material, such as a metal, which can include stainless steel, aluminum, or the like. In some embodiments, the rigid material is a ceramic, non-reactive polymer, or other suitable material.

The filter element 210 is or includes a thin sheet that includes a multilayer. Thickness of the filter element 210 does not exceed about 500 nanometers (nm). In some embodiments, the thickness does not exceed about 150 nm. Embodiments of the filter element 210 are described in greater detail with reference to FIGS. 2B-2D.

The filter element 210 can be mounted to or in the frame 220. In some embodiments, each of the frame 220 and the filter element 210 has circular profile in a plane formed by a first direction D1 and a second direction D2 transverse the first direction D1. The filter element 210 is exposed by the frame 220. The frame 220 can be ring-shaped, and may have an outer diameter and an inner diameter. The filter element 210 may have diameter that exceeds the inner diameter and does not exceed the outer diameter. In some embodiments, the frame 220 includes two rings that are stacked along a third dimension that is perpendicular to the first and second directions D1, D2. The filter element 210 may be held between the two rings of the frame 220, for example, by an adhesive, pressure (e.g., due to tightening screws or clamps), or the like.

In addition to holding the filter element 210 in place, the frame 220 can also be beneficial to reduce or remove waviness or other non-uniformities of the filter element 210. In some embodiments, adjustable rollers can be included in the frame 220 for fine-tuning tension across the filter element 210. A mechanism such as a winch or screw-driven system can be included to apply and adjust tension uniformly. Prior to final assembly of the filter assembly 200, the filter element 210 may be pre-tensioned to stretch out initial waviness, which can include stretching the filter element 210 over another, slightly larger frame to flatten the filter element 210 before final mounting. In some embodiments, a brief thermal treatment might be performed to improve flatness of the filter element 210 by allowing it to settle into a flat state under controlled conditions. In some embodiments, applying vibrations to the filter element 210 can be beneficial for the filter element to settle into a flat state. In some embodiments, a vacuum environment may be beneficial for pulling the filter element 210 flat, particularly when the filter element 210 can be mounted on another substrate via differential pressure.

FIGS. 2B, 2C, and 2D illustrate schematic views of the filter element 210, in accordance with some embodiments.

In FIG. 2B, the filter element 210 has rectangular or square profile in the plane formed by the first and second directions D1, D2. The filter element 210 can have width W1, length L1 and thickness or height H1. The thickness H1 can be along a third direction D3 that is perpendicular to the first and second directions D1, D2. In some embodiments, each of the width W1 and the length L1 can have dimension in a range of about 1 centimeter (cm) to about 15 cm. In some embodiments, the thickness H1 has dimension that does not exceed about 1 micrometer (um), such as being less than about 500 nm, about 150 nm, or another suitable value. In some embodiments, the width W1 and the length L1 have the same dimension, such that the profile of the filter element 210 is a square. In some embodiments, the dimensions of the width W1 and the length L1 are different than each other, such that the profile of the filter element 201 is a rectangle.

In FIG. 2C, the filter element 210 has circular profile in the plane formed by the first and second directions D1, D2. The filter element 210 can have diameter D210 and the thickness or height H1 (not separately labeled in FIG. 2C). In some embodiments, the diameter D210 can have dimension in a range of about 1 cm to about 15 cm. In some embodiments, the thickness H1 has dimension that does not exceed about 1 micrometer (um), such as being less than about 500 nm, about 150 nm, or another suitable value.

In FIG. 2D, the filter element 210 has elliptical profile in the plane formed by the first and second directions D1, D2. The filter element 210 can have major diameter M210, minor diameter N210 and the thickness or height H1 (not separately labeled in FIG. 2D). In some embodiments, each of the major diameter M210 and the minor diameter N210 can have dimension in a range of about 1 cm to about 15 cm. In some embodiments, the thickness H1 has dimension that does not exceed about 1 micrometer (um), such as being less than about 500 nm, about 150 nm, or another suitable value. In some embodiments, ratio of the major diameter M210 over the minor diameter N210 exceeds about 1.02.

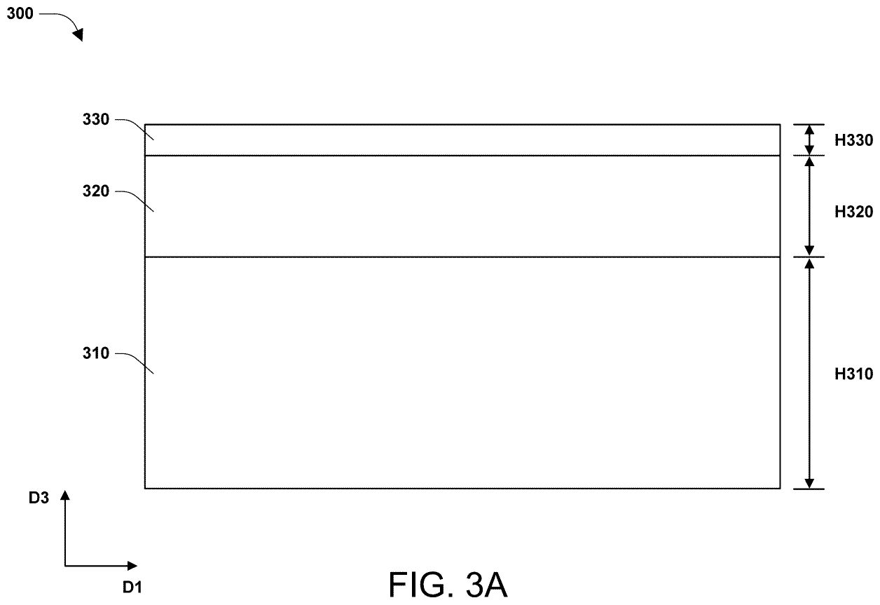

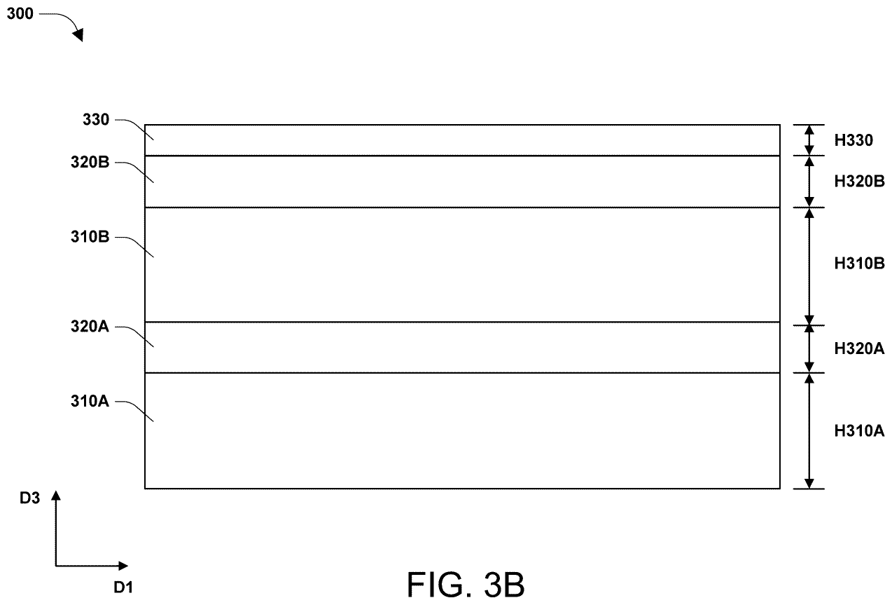

FIGS. 3A and 3B illustrate schematic cross-sectional side views of a filter element 300, in accordance with some embodiments. The filter element 300 is an embodiment of the filter element 200 described with reference to FIGS. 2A-2D.

In FIG. 3A, the filter element 300 includes a zirconium-based layer 310, a capping layer 330 on the zirconium-based layer 310 and an optional transition-metal-based layer 320 between the zirconium-based layer 310 and the capping layer 330.

The zirconium-based layer 310 is operable to transmit light radiation in the EUV spectrum while filtering light radiation outside the EUV spectrum. For example, the zirconium-based layer 310 is operable to allow photons of the in-band light 84IB to pass therethrough, while photons of the OOB light 84OOB are absorbed, reflected or both. The zirconium-based layer 310 can be or include zirconium, zirconium disilicide (ZrSi₂), combinations thereof, or the like. In some embodiments, the zirconium-based layer 310 has thickness H310 in a range of about 30 nm to about 350 nm. In some embodiments, thickness H310 of the zirconium-based layer 310 is about 70 nm.

The transition-metal-based layer 320 is operable to remove light radiation outside the EUV spectrum, which can be by reflection, absorption or both. In some embodiments, the multilayer including the zirconium-based layer 310 and the transition-metal-based layer 320 is operable to generate multilayer interference that reflections at an interface therebetween interfere destructively for the non-EUV wavelengths. The transition-metal-based layer 320 can be or include molybdenum, niobium, molybdenum disilicide (MoSi₂), yttrium, scandium, alloys thereof, combinations thereof (e.g., multilayers thereof), or the like. In some embodiments, the transition-metal-based layer 320 has thickness H320 in a range of about 10 nm to about 100 nm. In some embodiments, the thickness H320 of the transition-metal-based layer 320 is about 30 nm. Thickness of the multilayer including the zirconium-based layer 310 and transition-metal-based layer 320 does not exceed about 480 nm. In some embodiments, the transition-metal-based layer 320 is not included, such that the capping layer 330 is in direct contact with the zirconium-based layer 310.

The capping layer 330 is operable to prevent oxidation of the underlying layers, such as the transition-metal-based layer 320, the zirconium-based layer 310, or both. In some embodiments, the capping layer 330 can be or include a silicon-based dielectric, such as silicon carbide, silicon dioxide, silicon nitride, or the like. In some embodiments, the capping layer 330 has thickness H330 in a range of about 3 nm to about 20 nm. In some embodiments, the thickness H330 of the capping layer 330 is about 5 nm. The capping layer 330 having the thickness H330 that exceeds about 20 nm may attenuate the in-band light radiation in the EUV spectrum.

In some embodiments, the thickness H310 exceeds the thickness H320, which exceeds the thickness H330.

In some embodiments, intermixing can be present between materials of immediately adjacent pairs of the zirconium-based layer 310, the transition-metal-based layer 320, and the capping layer 330. In some embodiments, the intermixing has thickness that does not exceed about 3 nm. For example, a thin layer of intermixed zirconium and molybdenum may be formed at the interface of the zirconium-based layer 310 and the transition-metal-based layer 320, and thickness of the thin layer does not exceed about 3 nm.

In the system 10 or the system 10A, when the filter element 300 is included in the filter assembly 12 or the filter assembly 12A, the capping layer 330 faces or is proximal to the source of EUV light emission, such as the plasma 88 or the plasma 88A.

In FIG. 3B, the filter element 300 is similar in most respects to that described with reference to FIG. 3A. As depicted in FIG. 3B, in some embodiments, instead of a multilayer including a single zirconium-based layer 310 and a single transition-metal-based layer 320, the filter element 300 can include a multilayer that includes at least two zirconium-based layers 310A, 310B and at least two transition-metal-based layers 320A, 320B. For example, the filter element 300 can include a first zirconium-based layer 310A, a second zirconium-based layer 310B, a first transition-metal-based layer 320A, and a second transition-metal-based layer 320B. The capping layer 330 is on the second transition-metal-based layer 320B, which is on the second zirconium-based layer 310B, which is on the first transition-metal-based layer 320A, which is on the first zirconium-based layer 310A. First height H310A and second height H310B of the first and second zirconium-based layers 310A, 310B exceed third height H320A and fourth height H320B of the first and second transition-metal-based layers 320A, 320B, which exceed fifth height H330 of the capping layer. Two zirconium-based layers 310A, 310B and two transition-metal-based layers 320A, 320B are depicted in FIG. 3B. In some embodiments, additional zirconium-based layers and transition-metal-based layers are included in the multilayer, such that the multilayer includes three, four, five, or more each of the zirconium-based layers and the transition-metal-based layers.

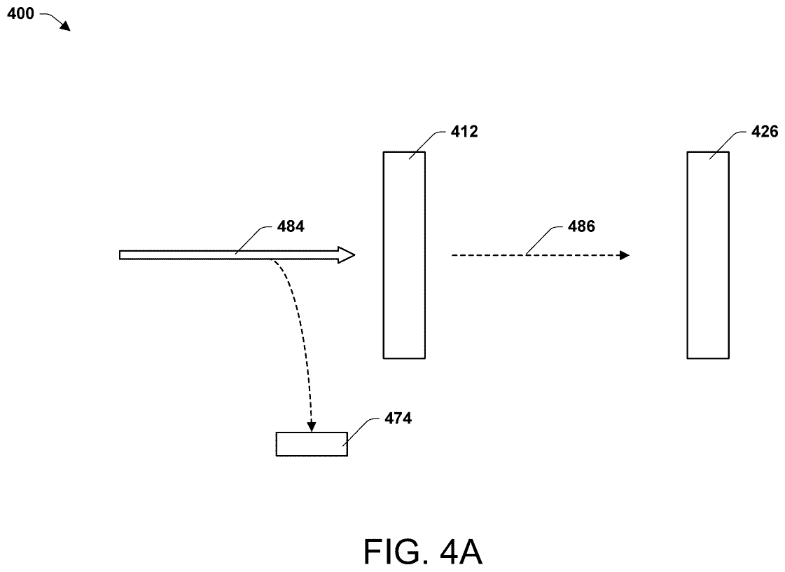

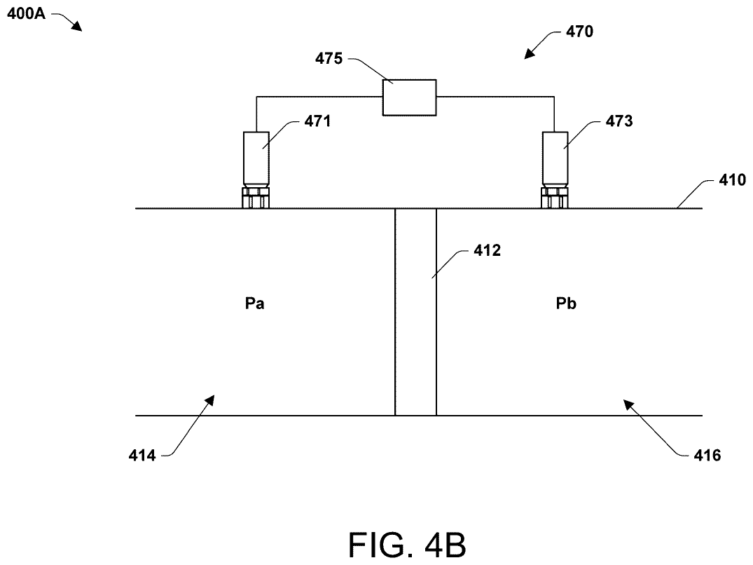

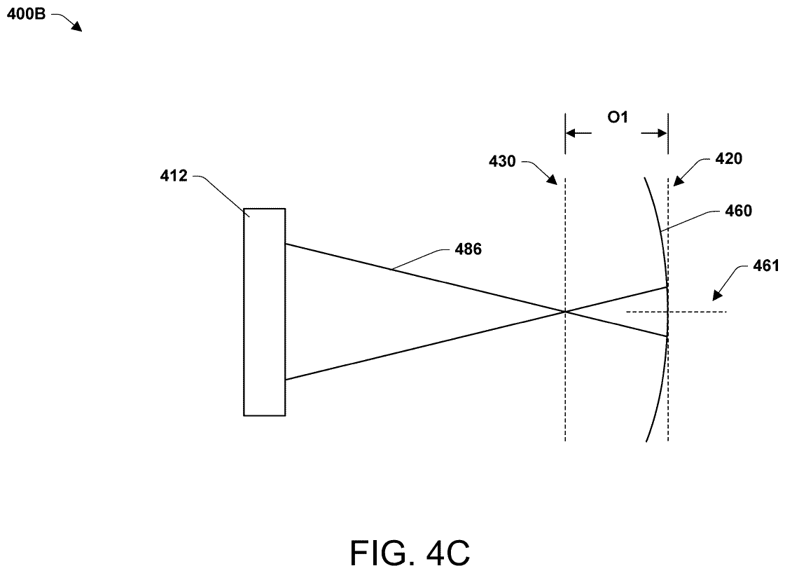

FIG. 4A illustrates a schematic view of a filter degradation detection system 400 (or simply “the detection system 400”), in accordance with some embodiments.

The detection system 400 includes a first sensor 474 and a second sensor 426. The first sensor 474 is operable to determine first brightness associated with first light 484 that is incident on a filter assembly 412, which can be the filter assembly 12, the filter assembly 12A, the filter assembly 200, or another similar filter assembly. The second sensor 426 is operable to determine second brightness associated with second light 486 that exits the filter assembly 412. As a filter element of the filter assembly 412 degrades, the second brightness may decrease, which may be a result of oxidization of the filter element. As a result, a brightness difference between the first brightness and the second brightness may increase. In response to the second brightness decreasing, the brightness difference increasing or both, a determination may be made as to whether the filter assembly 412 is degraded to a degree to which the filter assembly 412 or the filter element thereof can be scheduled for rework, repair, or replacement.

One or more threshold values may be selected for determining whether the filter assembly 412 is degraded. In some embodiments, a first threshold value is selected that is associated with the second brightness. In response to the second brightness exceeding the first threshold value, determination may be made that the filter assembly 412 is not degraded and semiconductor processing may proceed. In response to the second brightness not exceeding the first threshold value, determination may be made that the filter assembly 412 is degraded and semiconductor processing may be stopped, the filter assembly 412 may be reworked, replaced, repaired, or a combination thereof. In some embodiments, instead of comparing the second brightness with the first threshold value, a drop in the second brightness over time may be measured. For example, and initial second brightness may be determined immediately after the filter assembly 412 is installed, then the second brightness may be measured continuously or periodically and compared with the initial second brightness. In response to the drop in the second brightness exceeding a threshold value, the filter assembly 412 may be determined to be degraded and one or more of the described actions may be taken. The threshold value may be a percentage of brightness lost over time. In some embodiments, the threshold value may be in a range of about 5% to about 20%, or another suitable percentage.

In some embodiments, a second threshold value is selected that is associated with the brightness difference. In response to the brightness difference not exceeding the second threshold value, determination may be made that the filter assembly 412 is not degraded and semiconductor processing may proceed. In response to the brightness difference exceeding the second threshold value, determination may be made that the filter assembly 412 is degraded and semiconductor processing may be stopped, the filter assembly 412 may be reworked, replaced, repaired, or a combination thereof.

FIG. 4B illustrates a schematic view of a filter degradation detection system 400A (or simply “the detection system 400A”), in accordance with some embodiments.

In some embodiments, the filter assembly 412 is positioned in a tube 410 or at an end of the tube 410. The tube 410 can be the transport tube 14 described with reference to FIG. 1A. The filter assembly 412 being in, or against an end of, the tube 410 physically separates a first chamber 414 from a second chamber 416. The first chamber 414 can be the first chamber 122 and the second chamber 416 can be the second chamber 124, which are described with reference to FIG. 1A. The first chamber 414 may have a first pressure Pa and the second chamber 416 may have a second pressure Pb that is different than the first pressure Pa. In some embodiments, the second pressure Pb exceeds the first pressure Pa.

The detection system 400A includes a differential pressure sensor 470 that is operable to determine the first pressure Pa and the second pressure Pb. In some embodiments, the differential pressure sensor 470 includes a first pressure sensor 471, a second pressure sensor 473, and a controller 475. The first pressure sensor 471 is mounted to the tube 410 adjacent the first chamber 414 and can determine the first pressure Pa of the first chamber 414, which can include generating a first pressure value associated with the first chamber 414. The second pressure sensor 473 is mounted to the tube 410 adjacent the second chamber 416 and can determine the second pressure Pb of the second chamber 416, which can include generating a second pressure value associated with the second chamber 416. The controller 475 is in data or electrical communication with the first and second pressure sensors 471, 473, and is operable to determine a pressure difference value based on the first and second pressure values. For example, the pressure difference value can be equal to the second pressure value minus the first pressure value.

In operation, as the filter assembly 412 degrades, perforation of the filter assembly 412 can occur due to high velocity impact of tin debris on the filter element. Sufficient perforation of the filter element can result in a reduction in the pressure difference value. Namely, the first pressure Pa and the second pressure Pb may roughly equalize due to the perforation of the filter element which forms openings that connect the first chamber 414 to the second chamber 416.

In response to reduction of the pressure difference value to a value below a threshold value, the filter assembly 412 may be determined to be degraded, and the filter assembly 412 may be replaced, repaired, reworked, or the like. In some embodiments, the threshold value can be slightly above zero. In some embodiments, the threshold value can be a percentage of an expected pressure difference value associated with the filter assembly 412 that is substantially free of perforation. For example, the percentage can be in a range of about 0% to about 80%. Namely, a drop in the pressure difference value from the expected pressure difference value that exceeds about 20% can result in determining that the filter assembly 412 is degraded, in response to which, the filter assembly 412 may be replaced, repaired, reworked or the like.

FIG. 4C illustrates a schematic view of a filter degradation detection system 400B, in accordance with some embodiments.

In some embodiments, a focal point 430 is associated with light radiation 486 that is incident on a following mirror 460, such as a mirror 100 of the illuminator 140 or a mirror 110 of the POB 130. Position of the mirror 460 may be adjusted forward and backward along an axis 461 to correspond to the focal point 430. The position of the mirror 460 may be controlled by an actuator that is controlled by a controller. The mirror 460 may initially be positioned at a first focal point 420 that may be an expected or initial position associated with the filter assembly 412 being substantially free of oxidization. Due to the oxidization of the filter assembly 412 as the filter assembly 412 degrades, the light radiation 486 may have a second focal point 430 that is shifted relative to the first focal point 420, as depicted in FIG. 4C. The position of the mirror 460 may be shifted gradually over time from the first focal point 420 to the second focal point 430 via a control algorithm or autofocus algorithm performed by the controller. A shift O1 is depicted in FIG. 4C that is a measurement of distance between the first focal point 420 and the second focal point 430.

In operation, a threshold value may be selected that corresponds to degradation of the filter assembly 412. In response to the shift O1 exceeding the threshold value, it may be determined that the filter assembly 412 is degraded, and the filter assembly 412 may be replaced, repaired, reworked or the like. In response to the shift O1 not exceeding the threshold value, it may be determined that the filter assembly 412 is not degraded, and semiconductor processing may be performed with the filter assembly 412 in place.

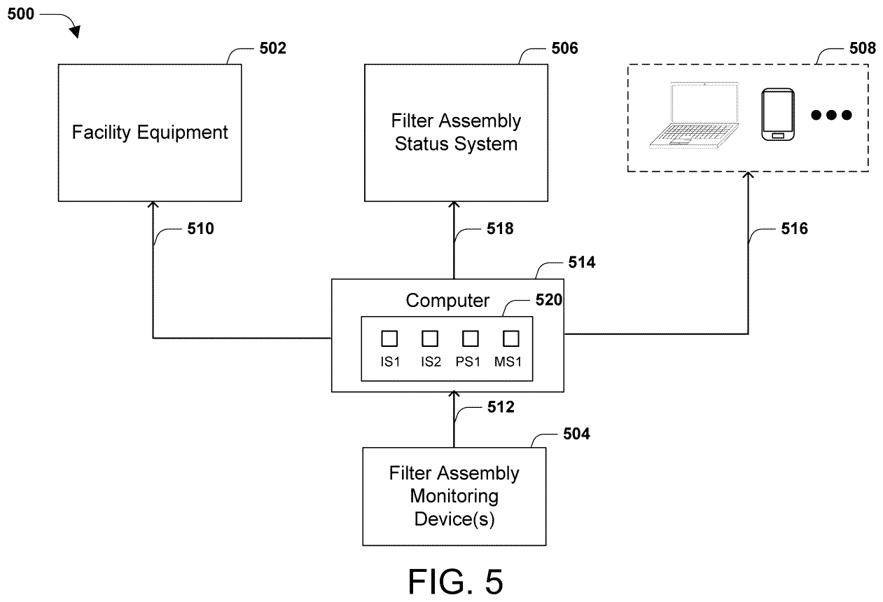

FIG. 5 illustrates a schematic view of a filter assembly monitoring system or “system” 500, in accordance with some embodiments. The system 500 comprises at least one of a set of filter assembly monitoring devices 504, facility equipment 502 of a facility, a computer 514, a filter assembly status system 506, or one or more client devices 508. The set of filter assembly monitoring devices 504 comprises filter assembly monitoring devices distributed at various locations of the facility. The filter assembly monitoring devices are used to determine measurements associated with devices and/or other equipment in the facility, such as the systems 10, 10A described with reference to FIGS. 1A-1D. In some embodiments, the filter assembly monitoring devices are used to determine measurements associated with the filter assemblies 12, 12A, 200, 412 described with reference to FIGS. 1A-4C.

In some embodiments, the set of filter assembly monitoring devices 504 transmit a set of monitoring signals 512 to the computer 514. In some embodiments, each signal of the set of monitoring signals 512 is transmitted by a monitoring device (e.g., the first and second sensors 74, 76), of the set of filter assembly monitoring devices 504, in a system of the facility.

In some embodiments, the set of monitoring signals 512 comprises a first monitoring signal from the first sensor 74. In some embodiments, the first sensor 74 comprises a wireless communication module that transmits the first monitoring signal to the computer 514 wirelessly. In some embodiments, the first sensor 74 transmits the first monitoring signal to the computer 514 over a wired connection between first sensor 74 and the computer 514. In some embodiments, the first monitoring signal is indicative of brightness associated with the first portion 841 sampled by the first sensor 74.

In some embodiments, the set of monitoring signals 512 comprises a second monitoring signal from the second sensor 76. In some embodiments, the second monitoring signal is indicative of brightness associated with the second portion 843 sampled by the second sensor 76. The first monitoring signal may be indicative of a first brightness associated with a first light (e.g., the light radiation 84), and the second monitoring signal may be indicative of a second brightness associated with a second light (e.g., the filtered light 84F). The first light and the second light may be positioned on either side of the filter assembly associated with the first and second sensors 74, 76.

In some embodiments, the computer 514 controls a display panel 520 comprising a set of status indicators associated with apparatuses (e.g., first, second, third and fourth sensors indicated by “IS1,” “IS2,” “PS1,” and “MS1,” respectively) of the system in the facility. The first and second sensors may be image sensors, such as the image sensor 26. The third sensor may be a differential pressure sensor, such as the differential pressure sensor 470. The fourth sensor may be a motion sensor, such as the controller described with reference to FIG. 4C. In some embodiments, an indicator of the set of status indicators comprises a light, such as an indicator light, that indicates whether a corresponding apparatus is associated with a degraded filter assembly, wherein the light being in a first state indicates that the corresponding apparatus is associated with the degraded filter assembly and/or the light being in a second state indicates that the corresponding apparatus is not associated with the degraded filter assembly. In some embodiments, the display panel 520 comprises a display configured to display an alert indicative of one or more detected filter assembly monitoring statuses of one or more apparatuses. In some embodiments, the first state corresponds to a first color emitted by the light, such as red or other color, and the second state corresponds to a second color emitted by the light, such as green or other color. The set of status indicators comprises at least one of a first indicator “IS1” associated with a first apparatus (e.g., the first sensor 74), a second indicator “IS2” associated with a second apparatus (e.g., the second sensor 76), a third indicator “PS1” associated with a third apparatus (e.g., the pressure differential sensor 470), a fourth indicator “MS1” associated with a fourth apparatus (e.g., the controller described with reference to FIG. 4C), or other indicator.

In some embodiments, the computer 514 provides one or more first signals 510 to the facility equipment 502. In some embodiments, the one or more first signals 510 are used to control at least some of the facility equipment 502, such as a lithography system of the facility and/or other equipment of the facility. In some embodiments, the one or more first signals 510 are generated using a signal generator of the computer 514. The one or more first signals 510 can be indicative of a degraded filter assembly of the lithography system. In some embodiments, the computer 514 transmits the one or more first signals 510 to the facility equipment 502 wirelessly, such as using a wireless communication device of the computer 514. In some embodiments, the computer 514 transmits the one or more first signals 510 to the facility equipment 502 over a physical connection between the computer 514 and the facility equipment 502. In some embodiments, the computer 514 transmits the one or more first signals 510 to a controller that controls one or more operations of the lithography system. In some embodiments, the controller controls removal of the filter assembly, for example, by a robot arm.

In some embodiments, the computer 514 transmits a second signal 518 to the filter assembly status system 506. The second signal 518 is generated using the signal generator of the computer 514. In some embodiments, the second signal 518 is indicative of at least one of (i) the set of filter assembly monitoring statuses, (ii) the list of apparatuses that are determined to have the degraded filter apparatus, or (iii) other information. In some embodiments, the computer 514 transmits the second signal 518 to the status system 506 wirelessly, such as using the wireless communication device of the computer 514. In some embodiments, the computer 514 transmits the second signal 518 to the status system 506 over a physical connection between the computer 514 and the status system 506. In some embodiments, the status system 506 triggers an alarm function based upon the second signal 518. In some embodiments, the status system 506 triggers the alarm function based upon the second signal 518 indicating that the filter apparatus is degraded. In some embodiments, in response to triggering the alarm function, an alarm message is displayed via a display of the status system 506. The alarm message comprises at least one of an indication that the filter apparatus is degraded, an indication of lead time to perform preventative maintenance, an indication comprising an instruction for the associated lithography system to cease operating (until the filter apparatus is replaced, for example), or other indication. In some embodiments, an alarm sound is output via a speaker connected to the filter assembly status system 506 in response to triggering the alarm function.

In some embodiments, the computer 514 transmits a third signal 516 to one or more client devices 508. The one or more client devices 508 comprise at least one of a phone, a smartphone, a mobile phone, a landline, a laptop, a desktop computer, hardware, or other type of client device. The third signal 516 is generated using the signal generator of the computer 514. In some embodiments, the third signal 516 is indicative of at least one of (i) the set of filter assembly monitoring statuses, (ii) the list of apparatuses that are determined to be associated with the filter assembly that is degraded, or (iii) other information. In some embodiments, the computer 514 transmits the third signal 516 to a client device of the one or more client devices 508 wirelessly, such as using the wireless communication device of the computer 514. In some embodiments, the computer 514 transmits the third signal 516 to a client device of the one or more client devices 508 over a physical connection between the computer 514 and the client device. In some embodiments, the third signal 516 comprises a message, such as at least one of an email, a text message, etc., transmitted in response to detecting the filter assembly that is degraded. In some embodiments, in response to detecting a filter apparatus is degraded, a telephonic call is made to a client device, such as a landline or a mobile phone, of the one or more client devices 508, such as using a dialer of the computer 514.

In some embodiments, the set of monitoring signals 512 are used as feedback based upon which operation of the facility equipment 502 is controlled by the computer 514. In some embodiments, the computer 514 controls operation of the facility equipment 502 based upon measurements provided by the set of monitoring signals 512. In some embodiments, operation of the facility equipment 502 is controlled using the one or more first signals 510. In some embodiments, a signal of the one or more first signals 510 is indicative of one or more instructions.

In some embodiments, the system 10 of the facility equipment 502 at least one of halts operation, removes or replaces the filter apparatus, or performs another operation in response to receiving a signal (of the one or more first signals 510) indicating that the filter apparatus is degraded. In some embodiments, the one or more first signals 510 comprise a signal transmitted to a machine, such as the system 10. In some embodiments, the signal instructs the machine to halt operation while the filter apparatus is undergoing preventative maintenance. In some embodiments, the signal allocates one or more resources (e.g., manpower, a robot, one or more tools, the replacement component, etc.) to the system 10 to replace the filter apparatus.

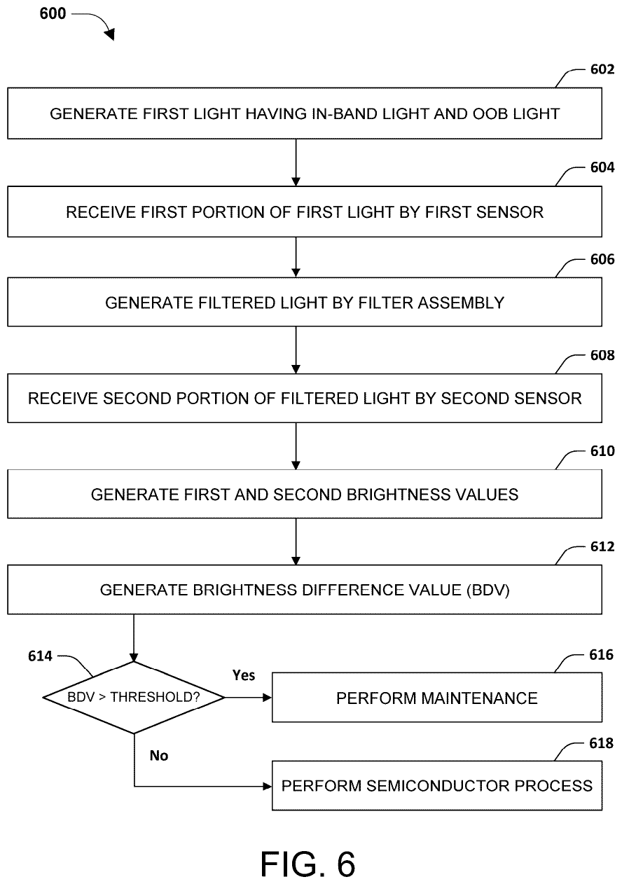

FIG. 6 is a flow diagram illustrating a method 600 of operating a system having a filter apparatus, in accordance with some embodiments.

The method 600 is illustrated in FIG. 6 in accordance with some embodiments.

At 602, first light is generated by plasma of a light source of a semiconductor processing tool. The first light includes in-band light in an extreme ultraviolet (EUV) spectrum and out-of-band (OOB) light outside the EUV spectrum.

At 604, prior to generating filtered light, a first portion of the first light is received by a first sensor.

At 606, filtered light is generated that includes the in-band light by removing the OOB light from the first light by a filter assembly having a filter element. The filter element includes a zirconium-based layer and a transition-metal-based layer on the zirconium-based layer. The filter assembly is positioned between the plasma and a collector mirror.

At 608, following generating the filtered light, a second portion of the filtered light is received by a second sensor.

At 610, a first brightness value associated with the first portion is generated, and a second brightness value associated with the second portion is generated.

At 612, a brightness difference value is generated based on the first brightness value and the second brightness value.

At 614, a determination is made whether the brightness difference value exceeds a threshold value.

At 616, in response to the brightness difference value exceeding the threshold value, a maintenance operation is performed on the filter assembly.

At 618, in response to the brightness difference value not exceeding the threshold value, a semiconductor process is performed on a semiconductor wafer by the semiconductor processing tool.

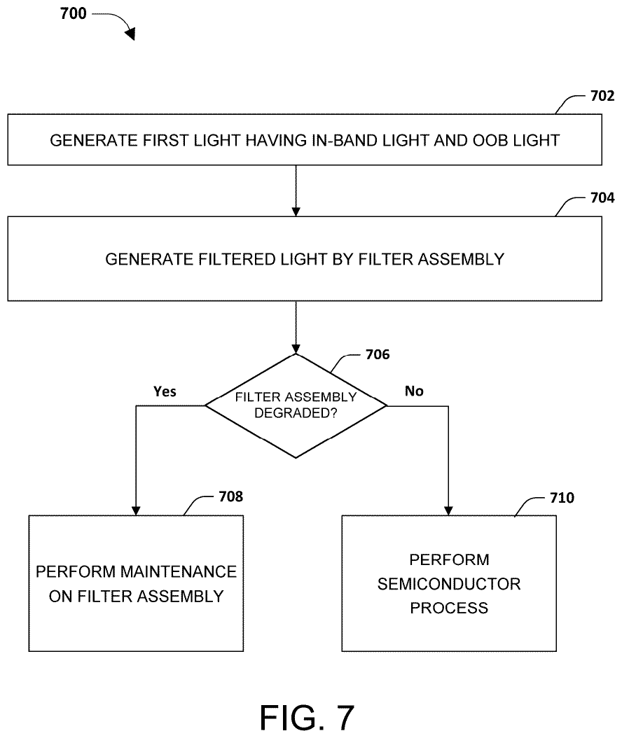

FIG. 7 is a flow diagram illustrating a method 700, in accordance with some embodiments.

The method 700 is illustrated in FIG. 7 in accordance with some embodiments.

At 702, the method 700 includes generating first light by a plasma of a light source of a semiconductor processing tool, the first light including in-band light in an extreme ultraviolet (EUV) spectrum and out-of-band (OOB) light outside the EUV spectrum.

At 704, the method 700 includes generating filtered light including the in-band light by removing the OOB light from the first light by a filter assembly positioned in direct contact with a tube. The filter assembly has a filter element that includes a zirconium-based layer and a transition-metal-based layer on the zirconium-based layer.

At 706, the method 700 includes determining whether the filter assembly is degraded.

At 708, the method 700 includes, in response to the filter assembly being degraded, performing a maintenance operation on the filter assembly.

At 710, the method 700 includes, in response to the filter assembly not being degraded, performing a semiconductor process on a semiconductor wafer by the semiconductor processing tool.

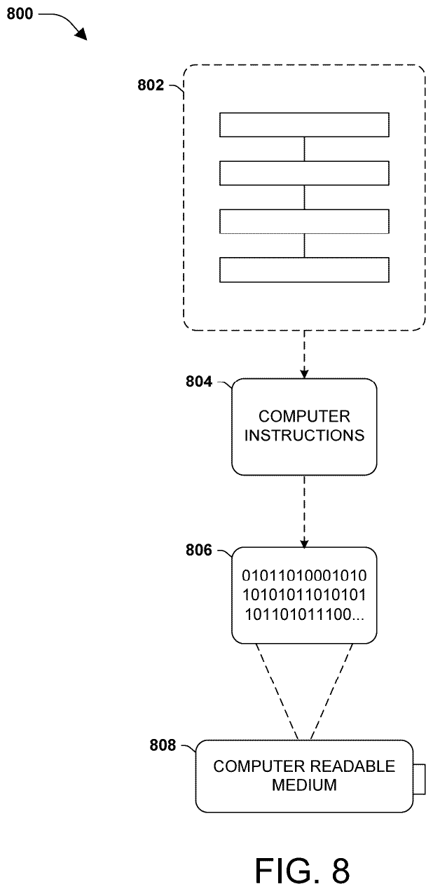

FIG. 8 illustrates an example computer-readable medium wherein processor-executable instructions configured to embody one or more of the provisions set forth herein may be comprised, according to some embodiments.

One or more embodiments involve a computer-readable medium comprising processor-executable instructions configured to implement one or more of the techniques presented herein. An exemplary computer-readable medium is illustrated in FIG. 8, wherein the embodiment 800 comprises a computer-readable medium 808 (e.g., a CD-R, DVD-R, flash drive, a platter of a hard disk drive, etc.), on which is encoded computer-readable data 806. This computer-readable data 806 in turn comprises a set of processor-executable computer instructions 804 configured to implement one or more of the principles set forth herein when executed by a processor. In some embodiments 800, the processor-executable computer instructions 804 are configured to implement a method 802, such as at least some of the aforementioned method(s) when executed by a processor. In some embodiments, the processor-executable computer instructions 804 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: generating first light by a plasma of a light source of a semiconductor processing tool, the first light including in-band light in an extreme ultraviolet (EUV) spectrum and out-of-band (OOB) light outside the EUV spectrum; generating filtered light including the in-band light by removing the OOB light from the first light by a filter assembly having a filter element that includes a zirconium-based layer and a transition-metal-based layer on the zirconium-based layer, the filter assembly being positioned between the plasma and a collector mirror; prior to generating the filtered light, receiving a first portion of the first light by a first sensor; following generating the filtered light, receiving a second portion of the filtered light by a second sensor; generating a first brightness value associated with the first portion; generating a second brightness value associated with the second portion; determining a brightness difference value based on the first brightness value and the second brightness value; determining whether the brightness difference value exceeds a threshold value; in response to the brightness difference value not exceeding the threshold value, performing a semiconductor process on a semiconductor wafer by the semiconductor processing tool; and in response to the brightness difference value exceeding the threshold value, performing a maintenance operation on the filter assembly.

In some embodiments, a method is provided. The method includes: generating first light by a plasma of a light source of a semiconductor processing tool, the first light including in-band light in an extreme ultraviolet (EUV) spectrum and out-of-band (OOB) light outside the EUV spectrum; generating filtered light including the in-band light by removing the OOB light from the first light by a filter assembly positioned in direct contact with a tube, the filter assembly having a filter element that includes a zirconium-based layer and a transition-metal-based layer on the zirconium-based layer; determining whether the filter assembly is degraded; in response to the filter assembly being degraded, performing a maintenance operation on the filter assembly; and in response to the filter assembly not being degraded, performing a semiconductor process on a semiconductor wafer by the semiconductor processing tool.

In some embodiments, a system is provided. The system includes: a light source operable to generate plasma that emits first light including in-band light in an extreme ultraviolet (EUV) spectrum and out-of-band (OOB) light outside the EUV spectrum; a collector mirror; a wafer stage, an optical path being defined from a first chamber of the light source, to the collector mirror, to the wafer stage; a mask stage positioned along the optical path between the collector mirror and the wafer stage; and a filter assembly positioned on the optical path, the filter assembly including a filter element that includes: a first zirconium-based layer; and a capping layer.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
generating first light by a plasma of a light source of a semiconductor processing tool, the first light including in-band light in an extreme ultraviolet (EUV) spectrum and out-of-band (OOB) light outside the EUV spectrum;
generating filtered light including the in-band light by removing the OOB light from the first light by a filter assembly having a filter element that includes a zirconium-based layer and a transition-metal-based layer on the zirconium-based layer, the filter assembly being positioned between the plasma and a collector mirror;
prior to generating the filtered light, receiving a first portion of the first light by a first sensor;
following generating the filtered light, receiving a second portion of the filtered light by a second sensor;
generating a first brightness value associated with the first portion;
generating a second brightness value associated with the second portion;
determining a brightness difference value based on the first brightness value and the second brightness value;
determining whether the brightness difference value exceeds a threshold value;
in response to the brightness difference value not exceeding the threshold value, performing a semiconductor process on a semiconductor wafer by the semiconductor processing tool; and
in response to the brightness difference value exceeding the threshold value, performing a maintenance operation on the filter assembly.

2. The method of claim 1, wherein receiving the second portion includes:
receiving the second portion of the filtered light by the second sensor, the second portion being obtained from a position that is between the filter assembly and the collector mirror.

3. The method of claim 1, wherein the semiconductor processing tool includes a mask stage positioned along an optical path from the plasma to a wafer stage position, and receiving the second portion includes:
receiving the second portion of the filtered light by the second sensor, the second portion being obtained from a position along the optical path that is between the collector mirror and the mask stage.

4. The method of claim 1, wherein the semiconductor processing tool includes a mask stage positioned along an optical path from the plasma to a wafer stage position, and receiving the second portion includes:
receiving the second portion of the filtered light by the second sensor that is an image sensor positioned at the wafer stage position.

5. The method of claim 1, wherein generating the filtered light includes:
generating the filtered light by the filter assembly that is in direct contact with an interface tube that is positioned between a first chamber in which the plasma is positioned and a second chamber in which the collector mirror is positioned.

6. The method of claim 5, wherein generating the filtered light includes:
generating the filtered light by the filter assembly that is mounted to an end of the interface tube that is positioned in the second chamber.

7. A method, comprising:
generating first light by a plasma of a light source of a semiconductor processing tool, the first light including in-band light in an extreme ultraviolet (EUV) spectrum and out-of-band (OOB) light outside the EUV spectrum;
generating filtered light including the in-band light by removing the OOB light from the first light by a filter assembly positioned in direct contact with a tube, the filter assembly having a filter element that includes a zirconium-based layer and a transition-metal-based layer on the zirconium-based layer;
determining whether the filter assembly is degraded;
in response to the filter assembly being degraded, performing a maintenance operation on the filter assembly; and
in response to the filter assembly not being degraded, performing a semiconductor process on a semiconductor wafer by the semiconductor processing tool.

8. The method of claim 7, wherein determining whether the filter assembly is degraded includes:
generating a first pressure value associated with a first portion of the tube defined on a first side of the filter assembly;
generating a second pressure value associated with a second portion of the tube defined on a second side of the filter assembly opposite the first side;
determining a pressure difference value based on the first pressure value and the second pressure value;
determining whether the pressure difference value exceeds a threshold value;
in response to the pressure difference value exceeding the threshold value, determining that the filter assembly is not degraded; and
in response to the pressure difference value not exceeding the threshold value, determining that the filter assembly is degraded.

9. The method of claim 7, wherein determining whether the filter assembly is degraded includes:
generating a position shift value associated with shift of a mirror of the semiconductor processing tool from a first position to a second position;
determining whether the position shift value exceeds a threshold value;
in response to the position shift value exceeding the threshold value, determining that the filter assembly is degraded; and
in response to the position shift value not exceeding the threshold value, determining that the filter assembly is not degraded.

10. The method of claim 7, wherein generating the filtered light includes:
generating the filtered light by the filter assembly having the filter element that includes a capping layer, the transition-metal-based layer being between the capping layer and the zirconium-based layer.

11. The method of claim 10, wherein generating the filtered light includes:
generating the filtered light by the filter assembly having the filter element that includes the capping layer that is a silicon-based layer.

12. The method of claim 11, wherein generating the filtered light includes:
generating the filtered light by the filter assembly having the filter element that includes the capping layer that is a silicon-based layer that includes a hydrophobic surface.

13. The method of claim 10, wherein generating the filtered light includes:
generating the filtered light by the filter assembly having the filter element that includes a second transition-metal-based layer and a second zirconium-based layer, the second transition-metal-based layer and the second zirconium-based layer being between the capping layer and the transition-metal-based layer.

14. A system, comprising:
a light source operable to generate plasma that emits first light including in-band light in an extreme ultraviolet (EUV) spectrum and out-of-band (OOB) light outside the EUV spectrum;
a collector mirror;
a wafer stage, an optical path being defined from a first chamber of the light source, to the collector mirror, to the wafer stage;
a mask stage positioned along the optical path between the collector mirror and the wafer stage; and
a filter assembly positioned on the optical path, the filter assembly including a filter element that includes:
a first zirconium-based layer; and
a capping layer.

15. The system of claim 14, wherein the filter element includes a first transition-metal-based layer positioned between the first zirconium-based layer and the capping layer.

16. The system of claim 15, wherein:
first thickness of the first zirconium-based layer is in a range of about 50 nanometers (nm) to about 90 nm;
second thickness of the first transition-metal-based layer is in a range of about 20 nm to about 40 nm; and
third thickness of the capping layer is in a range of about 3 nm to about 10 nm.

17. The system of claim 14, wherein the light source comprises:
a housing;
the first chamber in the housing, the first chamber being operable to generate the plasma that emits the first light;
a second chamber in the housing, the collector mirror being in the second chamber;
an interface tube that extends from the first chamber to the second chamber;
a first pressure sensor positioned in the first chamber; and
a second pressure sensor positioned in the second chamber.

18. The system of claim 17, wherein the filter assembly is positioned in the interface tube.

19. The system of claim 17, wherein the filter assembly is mounted to an end of the interface tube that is positioned in the second chamber.

20. The system of claim 14, wherein thickness of the filter element does not exceed about 150 nm.
